(19) United States
(12) Patent Application Publication
(10) Pub. No.: US 2014/0153164 A1
(43) Pub. Date: Jun. 5, 2014

(54) ELECTRONIC DEVICE ENCLOSURE WITH CUSHIONING MEMBERS

(71) Applicants: HON HAI PRECISION INDUSTRY CO., LTD., New Taipei (TW); HONG FU JIN PRECISION INDUSTRY (ShenZhen) CO., LTD, Shenzhen (CN)

(72) Inventors: WEI-KUANG LIANG, New Taipei (TW); WENG-TIANG TANG, New Taipei (MY); PEI-HUA ZHANG, Shenzhen (CN)

(21) Appl. No.: 13/928,995

(22) Filed: Jun. 27, 2013

(30) Foreign Application Priority Data
Dec. 4, 2012 (CN) 2012105107129

(51) Int. Cl. H05K 5/02

(52) U.S. Cl. CPC H05K 5/0217; H05K 5/0221
USPC 361/679.01

(57) ABSTRACT

An electronic device enclosure comprises a base panel and a cushioning member attached to the base panel. A mounting groove and a mounting opening are defined in the base panel. The cushioning member comprises a main plate mounted at the mounting groove and a pivot portion extending from the main plate. The pivot portion comprises a latch piece capable of engaging in the mounting opening. When the pivot portion is rotated to an unlocked position, the latch piece is aligned with the mounting opening and disengageable from the mounting opening, thereby detaching the cushioning member. When the pivot portion is rotated to a locked position relative to the panel, the latch piece is deviated from the mounting opening and engaged with the panel, thereby securing the cushioning member.

### BACKGROUND

1. Technical Field

The present disclosure relates to an electronic device enclosure with cushioning members.

2. Description of Related Art

An electronic device comprises a base wall and a plurality of cushioning members mounted in the base wall. The plurality of cushioning members slightly protrude from the base wall. When the electronic device is placed on a desk, the plurality of cushioning members is placed on the desk and supports the electronic device, which facilitates heat dissipation of the electronic device and prevents the base wall from directly rubbing the desk. However, it's inconvenient to mount or dismount the plurality of cushioning members.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, exploded view of an electronic device enclosure in accordance with an embodiment.

FIG. 2 is similar to FIG. 1, but viewed from another aspect.

FIG. 3 is an assembled view of the electronic device enclosure of FIG. 2, showing a cushioning member in a locked position.

FIG. 4 is an assembled view of the electronic device enclosure of FIG. 2, showing the cushioning member in an unlocked position.

FIG. 5 is similar to FIG. 4, but viewed from another aspect.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

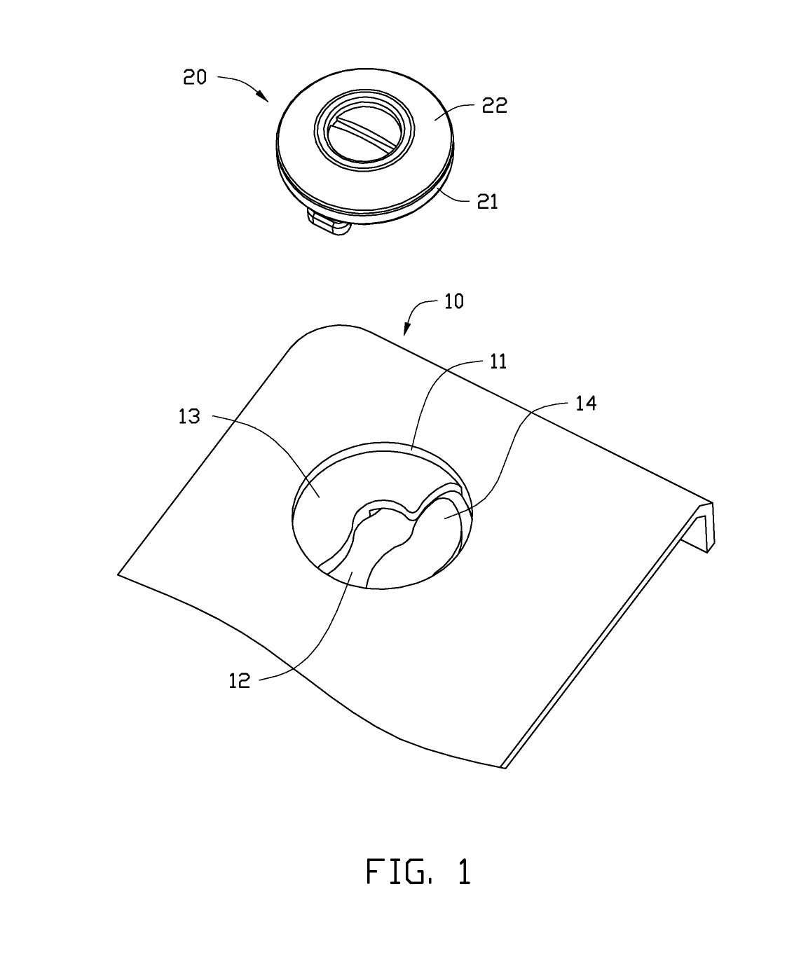

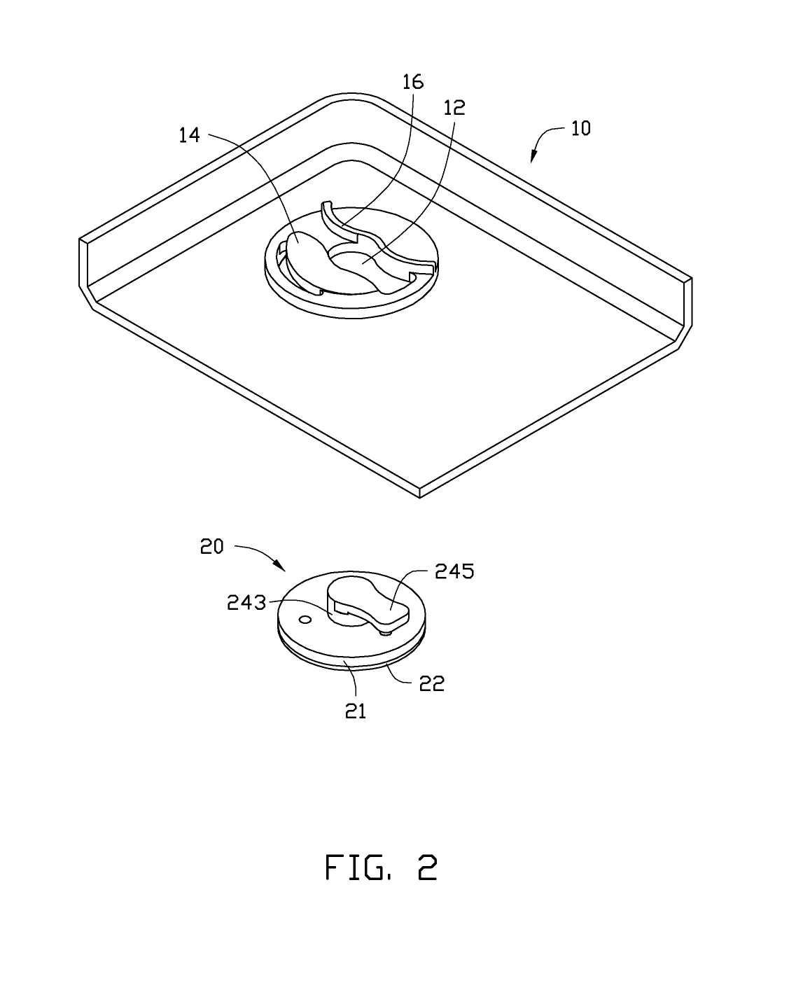

FIGS. 1 and 2 show an embodiment of an electronic device enclosure comprising a base panel 10 and a cushioning member 20. A mounting groove 11 and a mounting opening 12 are defined in the base panel 10. The base panel 10 comprises a first blocking portion 13 and a second blocking portion 14. The first blocking portion 13 and the second blocking portion 14 are connected to an inner edge of the mounting groove 11. The mounting opening 12 is located between the first blocking portion 13 and the second blocking portion 14. A first end of the mounting opening 12 is connected to the inner edge of the mounting groove 11. A second end of the mounting opening 12 is located at a central portion of the mounting groove 11. An outer surface of the first blocking portion 13 lies on the same plane as the outer surface of the base panel 10. A blocking flange 16 extends substantially perpendicularly from an inner side of the first blocking portion 13. The second blocking portion 14 is a resilient piece that is tilted towards an inner side of the base panel 10.

The cushioning member 20 comprises a main plate 21, a circular cover 22 mounted on the main plate 21, and a pivot portion 24 extending from a central portion of the main plate 21. The pivot portion 24 comprises a pivot shaft 243 with an outer end received in a central opening of the circular cover 22. A groove 241 is defined in the outer end of the pivot shaft 243 for facilitating rotating the pivot portion 24 by a screw driver. A latch piece 245 extends substantially perpendicularly from an inner end of the pivot shaft 243 corresponding to the mounting opening 12. The latch piece 245 is substantially parallel to the main plate 21. An outer surface of the circular cover 22 protrudes outwardly and has an arc shape. An outer surface of the pivot portion 24 is consistent with the outer surface of the circular cover 22.

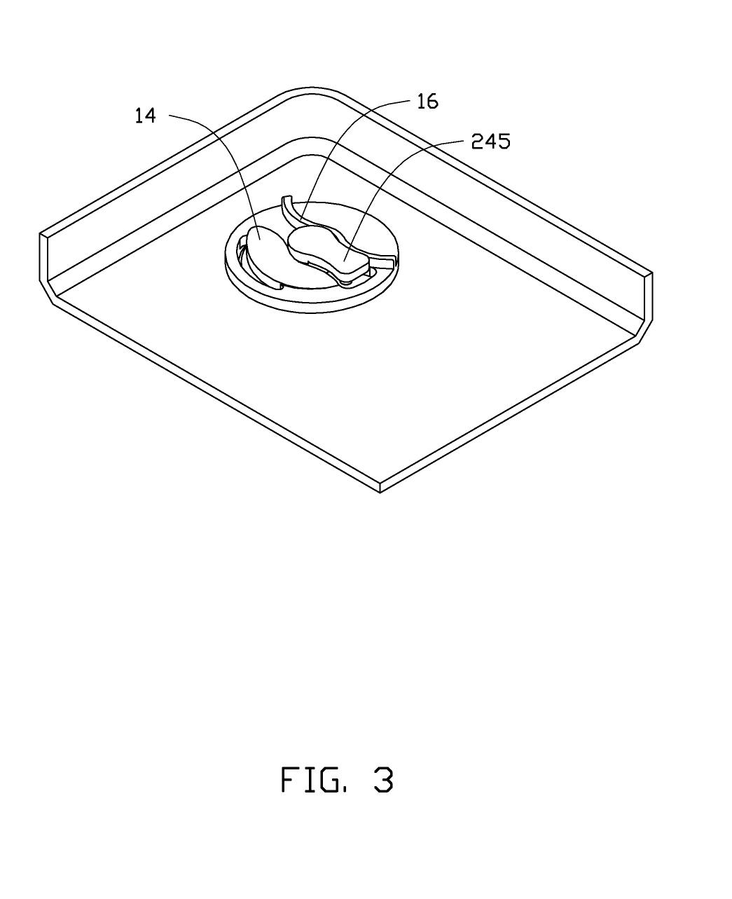

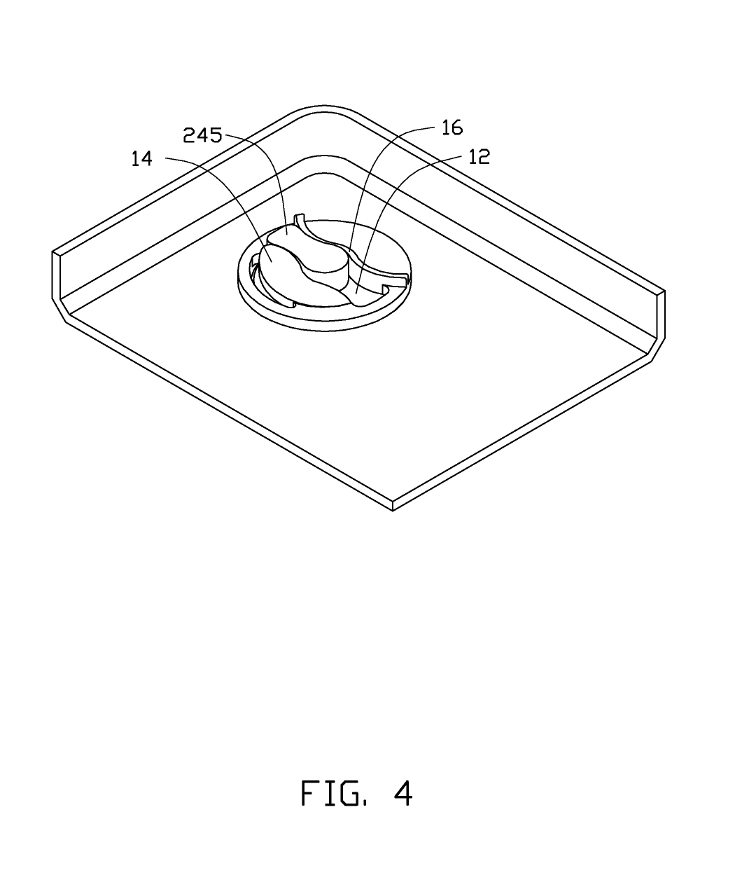

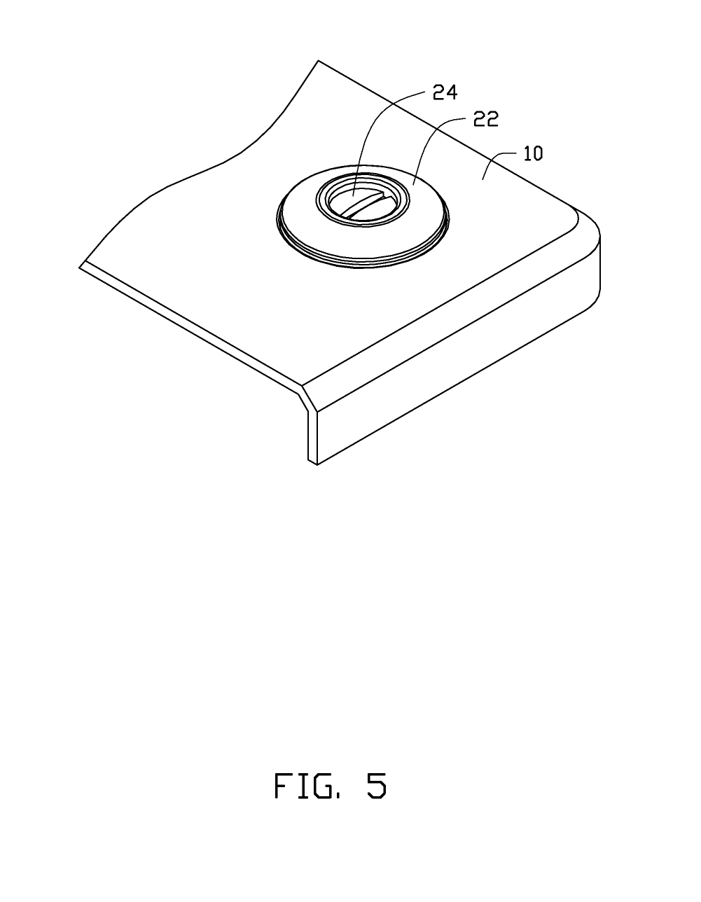

FIGS. 3 to 5 show in assembly, the latch piece 245 extends through the mounting opening 12. The pivot portion 24 is rotated 180 degrees from an unlocked position (see FIG. 3) to a locked position (see FIG. 4) in a clockwise direction. The latch piece 245 deforms the second blocking portion 14 until the latch piece 245 is moved across the second blocking portion 14. In the locked position, the second blocking portion 14 rebounds to its natural position. The latch piece 245 abuts against an inner side of the first blocking portion 13 and is clamped between the blocking flange 16 and the second blocking portion 14. The cushioning member 20 is securely attached to the base panel 10. The main plate 21 abuts the first blocking portion 13 and the second blocking portion 14. The cushioning member 20 slightly protrudes from the outer surface of the base panel 10.

To detach the cushioning member 20 from the base panel 10, the second blocking portion 14 is pressed towards an outer side of the base panel 10. The latch piece 245 is not blocked by the second blocking portion 14 and rotated 180 degrees in a counter-clockwise direction. The latch piece 245 returns to the unlocked position and is disengaged from the mounting opening 12.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An electronic device enclosure comprising:
a base panel defining a mounting groove and a mounting opening in communication with the mounting groove;
a cushioning member comprising a main plate, mounted at the mounting groove, and a pivot portion, extending from the main plate, the pivot portion comprising a latch piece capable of engaging in the mounting opening;
wherein when the pivot portion is rotated to an unlocked position, the latch piece is aligned with the mounting opening and disengageable from the mounting opening to detach the cushioning member from the base panel; and when the pivot portion is rotated to a locked position from the unlocked position, the latch piece is not aligned with the mounting opening and engaged with the base panel, thereby securing the cushioning member to the base panel.

2. The electronic device enclosure of claim 1, wherein the cushioning member further comprises a circular cover, mounted on the main plate, and an outer surface of the circular cover, protrudes outwardly from the base panel and has an arc shape.

3. The electronic device enclosure of claim 2, wherein the pivot portion comprises a pivot shaft with an outer end received in a central opening of the circular cover, and the latch piece extends substantially perpendicularly from an inner end of the pivot shaft.

4. The electronic device enclosure of claim 3, wherein the outer end and the inner end protrudes from opposite sides of the main plate, and the latch piece is substantially parallel to the main plate.

5. The electronic device enclosure of claim 4, wherein a groove is defined in the outer end of the pivot shaft for facilitating rotating the pivot portion.

6. The electronic device enclosure of claim 1, wherein the base panel comprises a first blocking portion and a second blocking portion, which are connected to an inner edge of the mounting groove; and the mounting opening is located between the first blocking portion and the second blocking portion.

7. The electronic device enclosure of claim 6, wherein a first end of the mounting opening is connected to the inner edge of the mounting groove, and a second end of the mounting opening is located at a central portion of the mounting groove.

8. The electronic device enclosure of claim 7, wherein a blocking flange extends substantially perpendicular from an inner side of the first blocking portion, and the latch piece is clamped between the blocking flange and the second blocking portion in the locked position.

9. The electronic device enclosure of claim 8, wherein the second blocking portion is a resilient piece that is tilted towards an inner side of the base panel.

10. The electronic device enclosure of claim 1, wherein the cushioning member protrudes from an outer surface of the base panel in the locked position.

11. An electronic device enclosure comprising:
a base panel comprising a first blocking portion and a second blocking portion, a mounting opening being defined in the base panel and located between the first blocking portion and the second blocking portion;
a cushioning member comprising a main plate abutting outer sides of the first blocking portion and the second blocking portion, and a pivot portion extending from the main plate, the pivot portion comprising a latch piece capable of engaging in the mounting opening;
wherein when the pivot portion is rotated to an unlocked position, the latch piece is aligned with the mounting opening and disengageable from the mounting opening to detach the cushioning member from the base panel; and when the pivot portion is rotated to a locked position from the unlocked position, the latch piece is abut against an inner side of the first blocking portion and clamped by the first blocking portion and the second blocking portion, thereby securing the cushioning member to the base panel.

12. The electronic device enclosure of claim 11, wherein the cushioning member further comprises a circular cover mounted on the main plate, and an outer surface of the circular cover protrudes outwardly from the base panel and has an arc shape.

13. The electronic device enclosure of claim 12, wherein the pivot portion comprises a pivot shaft with an outer end received in a central opening of the circular cover, and the latch piece extends substantially perpendicularly from an inner end of the pivot shaft.

14. The electronic device enclosure of claim 13, wherein the outer end and the inner end protrudes from opposite sides of the main plate, and the latch piece is substantially parallel to the main plate.

15. The electronic device enclosure of claim 14, wherein a groove is defined in the outer end of the pivot shaft for facilitating rotating the pivot portion.

16. The electronic device enclosure of claim 11, wherein a mounting groove is defined in the base panel, the first blocking portion and the second blocking portion are connected to an inner edge of the mounting groove, and the main plate is mounted at the mounting opening.

17. The electronic device enclosure of claim 16, wherein a first end of the mounting opening is connected to the inner edge of the mounting groove, and a second end of the mounting opening is located at a central portion of the mounting groove.

18. The electronic device enclosure of claim 17, wherein a blocking flange extends substantially perpendicularly from an inner side of the first blocking portion, and the latch piece is clamped between the blocking flange and the second blocking portion in the locked position.

19. The electronic device enclosure of claim 8, wherein the second blocking portion is a resilient piece that is tilted towards an inner side of the base panel.

20. The electronic device enclosure of claim 11, wherein an angle between the locked position and the unlocked position is about 180 degrees.
